(19) United States
(12) Patent Application Publication
(10) Pub. No.: US 2009/0246406 A1
(43) Pub. Date: Oct. 1, 2009

(54) PLASMA PROCESSING APPARATUS, CHAMBER INTERNAL PART, AND METHOD OF DETECTING LONGEVITY OF CHAMBER INTERNAL PART

(75) Inventors: Hiroyuki Nakayama, Nirasaki-shi (JP); Tsuyoshi Moriya, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/412,039

(22) Filed: Mar. 26, 2009

Related U.S. Application Data
(60) Provisional application No. 61/050,672, filed on May 6, 2008.

(30) Foreign Application Priority Data
Mar. 28, 2008 (JP) 2008-087728

(51) Int. Cl. H05H 1/24; C23C 16/00

(52) U.S. Cl. 427/569; 118/723 R

(57) ABSTRACT

A plasma processing apparatus that can accurately detect the longevity of a chamber internal part to eliminate the waste of the replacement of the chamber internal part that has not reached its end of longevity and prevent the occurrence of troubles caused by continuously using the chamber internal part that has reached its end of longevity. In the chamber internal part, at least one longevity detecting elemental layer comprised of an element different from a constituent material of the chamber internal part is buried.

### BACKGROUND OF THE INVENTION

1. Field of the Invention

The present invention relates to a plasma processing apparatus, a chamber internal part, and a method of detecting the longevity of the chamber internal part, and in particular to a plasma processing apparatus, a chamber internal part, and a method of detecting the longevity of the chamber internal part, which make it possible to accurately detect the longevity of the chamber internal part.

2. Description of the Related Art

Chamber internal parts of a plasma processing apparatus such as a focus ring made of silicon, an electrode, and an insulator made of quartz wear due to sputtering using plasma or the like, and hence they are treated as consumables that are replaced on a regular basis.

It is very difficult to predict or detect the timing of the replacement of chamber internal parts as consumables, and there are problems such as the waste of the replacement of chamber internal parts before they reach their ends of longevity, generation of particles caused by abnormal discharge arising from, for example, a gap formed between chamber internal parts by continuously using them even after they reach their ends of longevity, and so on.

Conventionally, the longevity of a chamber internal part as a consumable is set using, for example, an operating time as a guide. Specifically, the longevity of a chamber internal part is set to, for example, 200 hours in advance, and when an operating time of 200 hours has elapsed, an alarm indicating that it is necessary to replace the chamber internal part is sounded, and in accordance with this alarm, the chamber internal part is replaced.

However, the longevity of a chamber internal part varies according to the type of processing to be carried out, the status of use of a plasma processing apparatus, and so on, and does not always correspond to its operating time. Thus, the replacement of a chamber internal part using an operating times as a guide cannot eliminate the waste of the replacement of the chamber internal part and problems arising from abnormal discharge.

Accordingly, various techniques for coping with problems such as abnormal discharge in plasma processing apparatuses have been proposed.

Specifically, as an example of prior art publications concerning plasma processing apparatuses that predict or detect the occurrence of abnormal discharge, there is Japanese Laid-open Patent Publication (Kokai) No. 2003-234332. In Japanese Laid-open Patent Publication (Kokai) No. 2003-234332, a plasma processing apparatus is disclosed which is provided with a radio frequency power source that applies radio frequency electrical power to an upper electrode of the plasma processing apparatus to produce a DC bias potential, and an abnormal discharge determining means for determining whether abnormal discharge has occurred or not based on the DC bias potential produced in the upper electrode, and in which a bias potential applied to the upper electrode disposed such as to face a wafer and a bias potential applied to a lower electrode on which the wafer is mounted are monitored, and changes in the bias potentials are extracted so as to detect or predict the occurrence of abnormal discharge.

Moreover, as an example of prior art publications describing techniques for predicting the status of an object to be processed in a plasma processing apparatus or the status of the apparatus, there is Japanese Laid-open Patent Publication (Kokai) No. 2004-335841. In Japanese Laid-open Patent Publication (Kokai) No. 2004-335841, a predicting method for a plasma processing apparatus is disclosed which is a method of predicting the status of the plasma processing apparatus or the status of an object to be processed based on operation data on the plasma processing apparatus and data on results of processing. In this method, data for use in prediction is selected based on a multivariable analysis, a regression formula model is created using the selected data, and the status of the object to be processed or the status of the plasma processing apparatus is predicted based on the model.

Moreover, as an example of prior art publications describing techniques for preventing unnecessary processing and damage to an object to be processed in a plasma processing apparatus, there is Japanese Laid-open Patent Publication (Kokai) No. H10-335308. In Japanese Laid-open Patent Publication (Kokai) No. H10-335308, a plasma processing method is disclosed which is comprised of a plasma producing step of discharging electricity through a process gas to produce plasma, a step of subjecting an object to be processed to plasma processing using the produced plasma, a step of dividing light emitted from the plasma into spectrums and detecting a spectral emission intensity ratio of CF₂ and C₂ during the plasma processing, and a step of comparing the detected value and a reference value obtained in advance to determine whether the plasma processing is to be suspended or not. According to this method, unnecessary processing or damage to the object to be processed can be prevented.

However, according to the above described prior arts, the longevity of a chamber internal part in a plasma processing apparatus cannot be accurately detected, and hence problems such as the waste of the replacement of a chamber internal part that has not reached its end of longevity, and abnormal discharge caused by continuously using a chamber internal part that has reached its end of longevity cannot be solved.

### SUMMARY OF THE INVENTION

The present invention provides a plasma processing apparatus, a chamber internal part, and a method of detecting the longevity of the chamber internal part, which can accurately detect the longevity of the chamber internal part to eliminate the waste of the replacement of the chamber internal part that has not reached its end of longevity and prevent the occurrence of troubles caused by continuously using the chamber internal part that has reached its end of longevity.

Accordingly, in a first aspect of the present invention, there is provided a chamber internal part applied to a plasma processing apparatus, comprising at least one longevity detecting elemental layer buried therein and comprised of an element different from a constituent material of the chamber internal part.

According to the first aspect of the present invention, in a chamber internal part applied to a plasma processing apparatus, at least one longevity detecting elemental layer comprised of an element different from a constituent material of the chamber internal part is buried. Thus, the location of the longevity detecting elemental layer to be buried is selected, and when the chamber internal part wears and, for example, reaches its end of longevity, and a plasma emission spectrum of the element different from the constituent material of the chamber internal part is produced, the longevity of the chamber internal part can be accurately detected by detecting the plasma emission spectrum. Therefore, it is possible to eliminate the waste of the replacement of the chamber internal part that has not reached its end of longevity, and prevent the occurrence of troubles caused by continuously using the chamber internal part that has reached its end of longevity.

The first aspect of the present invention can provide a chamber internal part, wherein the longevity detecting elemental layer is buried correspondingly to a surface of the chamber internal part which is most susceptible to wear.

According to the first aspect of the present invention, because the longevity detecting elemental layer is buried correspondingly to the surface that is most susceptible to wear, it can be accurately detected that the chamber internal part has reached its end of longevity.

The first aspect of the present invention can provide a chamber internal part, wherein the longevity detecting elemental layer is buried at a depth corresponding to a maximum permissible wear thickness of the chamber internal part.

According to the first aspect of the present invention, because the longevity detecting elemental layer is buried at the depth corresponding to the maximum permissible wear thickness of the chamber internal part, it can be accurately detected that the chamber internal part has reached its end of longevity.

The first aspect of the present invention can provide a chamber internal part, wherein another longevity detecting elemental layer is provided between the longevity detecting elemental layer and the surface and is caused to act as an attention drawing layer, and a longevity detecting elemental layer that is provided at a location deeper than the attention drawing layer and of which depth corresponds to the maximum permissible wear thickness of the chamber internal part is caused to act as a warning layer.

According to the first aspect of the present invention, because another longevity detecting elemental layer is provided between the longevity detecting elemental layer and the surface and is caused to act as the attention drawing layer, and the longevity detecting elemental layer that is provided at the location deeper than the attention drawing layer is caused to act as the warning layer, it can be predicted that the chamber internal part will reach its end of longevity, and inconveniences caused by the chamber internal part reaching its end of longevity can be reliably prevented.

The first aspect of the present invention can provide a chamber internal part, wherein the attention drawing layer and the warning layer comprise respective different elements.

According to the first aspect of the present invention, because the attention drawing layer and the warning layer are comprised of respective different elements, it can be accurately determined whether the chamber internal part has worn down to the attention drawing layer or the warning layer.

The first aspect of the present invention can provide a chamber internal part, wherein the element different from the constituent material produces a plasma emission spectrum having a peak in a specific wavelength range or having a specific peak over a wide wavelength range.

According to the first aspect of the present invention, because the element that forms the longevity detecting elemental layer and is different from the constituent material produces a plasma emission spectrum having a peak in a specific wavelength range or having a specific peak over a wide wavelength range, the longevity of the chamber internal part can be detected based on a change in the pattern of a spectrum in a specific wavelength range in which emission is predicted in advance or a spectrum in a wide wavelength range.

The first aspect of the present invention can provide a chamber internal part, wherein the element comprises a metal.

According to the first aspect of the present invention, because the element forming the longevity detecting elemental layer is comprised of a metal, preparation of the chamber internal part having the longevity detecting elemental layer buried at a predetermined depth becomes relatively easy.

The first aspect of the present invention can provide a chamber internal part, wherein the metal comprises a transition metal.

According to the first aspect of the present invention, the metal forming the longevity detecting elemental layer is comprised of a transition metal, and hence by selecting the type of metal, a spectrum can be reliably detected, so that the longevity of the chamber internal part can be accurately detected without adversely affecting plasma processing.

The first aspect of the present invention can provide a chamber internal part, wherein the transition metal is at least one of scandium (Sc), dysprosium (Dy), neodymium (Nd), thorium (Tm), holmium (Ho), and thorium (Th).

According to the first aspect of the present invention, because the transition metal is at least one of scandium (Sc), dysprosium (Dy), neodymium (Nd), thorium (Tm), holmium (Ho), and thorium (Th), preparation of the chamber internal part having the longevity detecting elemental layer buried at a predetermined depth becomes relatively easy, and plasma processing is not adversely affected.

The first aspect of the present invention can provide a chamber internal part, wherein the chamber internal part is at least one of a focus ring, an electrode, an electrode protecting member, an insulator, an insulating ring, a bellows cover, and a baffle plate.

According to the first aspect of the present invention, because the chamber internal part is at least one of a focus ring, an electrode, an electrode protecting member, an insulator, an insulating ring, a bellows cover, and a baffle plate, the lives of these chamber internal parts treated as consumables can be detected.

Accordingly, in a second aspect of the present invention, there is provided a plasma processing apparatus comprising a plurality of chamber internal parts, wherein longevity detecting elemental layers comprised of elements other than constituent materials of the chamber internal parts are buried in the respective ones of the plurality of chamber internal parts.

According to the second aspect of the present invention, because in the respective ones of the plurality of chamber internal parts, the longevity detecting elemental layers comprised of elements other than the constituent materials of the chamber internal parts are buried, the longevity of each chamber internal part can be detected by detecting a plasma emission spectrum comprised of an element that is different from the constituent material of the chamber internal part and produced when the chamber internal part wears. It is thus possible to eliminate the waste of the replacement of the chamber internal part that has not reached its end of longevity, and prevent the occurrence of troubles caused by continuously using the chamber internal part that has reached its end of longevity.

The second aspect of the present invention can provide a plasma processing apparatus, wherein the longevity detecting elemental layers comprise elements differing according to the chamber internal parts.

According to the second aspect of the present invention, because the longevity detecting elemental layers are comprised of elements differing according to the chamber internal parts, the chamber internal parts that have reached their ends of longevity can be identified by detecting plasma emission spectrums specific to the respective elements.

Accordingly, in a third aspect of the present invention, there is provided a method of detecting a longevity of a chamber internal part, comprising carrying out plasma processing using a plasma processing apparatus having incorporated therein at least one chamber internal part in which a longevity detecting elemental layer comprised of an element other than a constituent material is buried at a predetermined depth below a surface, and detecting a plasma emission spectrum arising from the longevity detecting elemental layer to detect a longevity of the chamber internal part when the chamber internal part has worn due to plasma discharge.

According to the third aspect of the present invention, plasma processing is carried out using the plasma processing apparatus having incorporated therein at least one chamber internal part in which the longevity detecting elemental layer comprised of an element other than the constituent material is buried, and when the chamber internal part has worn due to plasma discharge, a plasma emission spectrum arising from the longevity detecting elemental layer is detected to detect the longevity of the chamber internal part. Therefore, the longevity of the chamber internal part can be accurately detected, and it is possible to eliminate the waste of the replacement of the chamber internal part that has not reached its end of longevity, and prevent the occurrence of troubles caused by continuously using the chamber internal part that has reached its end of longevity.

The third aspect of the present invention can provide a method of detecting a longevity of a chamber internal part, wherein the plasma processing apparatus has the plurality of chamber internal parts incorporated therein, and the longevity detecting elemental layers in the plurality of chamber internal parts comprise respective different elements, and the chamber internal parts that have reached their ends of longevity are identified by detecting plasma emission spectrums specific to the respective elements.

According to the third aspect of the present invention, because the longevity detecting elemental layers in the plurality of chamber internal parts are comprised of respective different elements, and the chamber internal parts that have reached their ends of longevity are identified by detecting plasma emission spectrums specific to the respective elements, waste can be eliminated by replacing only the chamber internal parts that have reached their ends of longevity.

The features and advantages of the invention will become more apparent from the following detailed description taken in conjunction with the accompanying drawings.

### BRIEF DESCRIPTION OF THE DRAWINGS

FIG. 1 is a cross-sectional view schematically showing the construction of a substrate processing apparatus as a plasma processing apparatus according to an embodiment of the present invention;

FIG. 2 is an enlarged cross-sectional view showing a focus ring shown in FIG. 1 and an insulator not shown in FIG. 1 as chamber internal parts and their vicinities;

FIG. 3 is an enlarged cross-sectional view showing an inner electrode shown in FIG. 1; and

FIG. 4 is flow chart showing the procedure of a method of detecting the longevity of a chamber internal part.

### DETAILED DESCRIPTION OF PREFERRED EMBODIMENTS

The present invention will now be described in detail with reference to the drawings showing a preferred embodiment thereof.

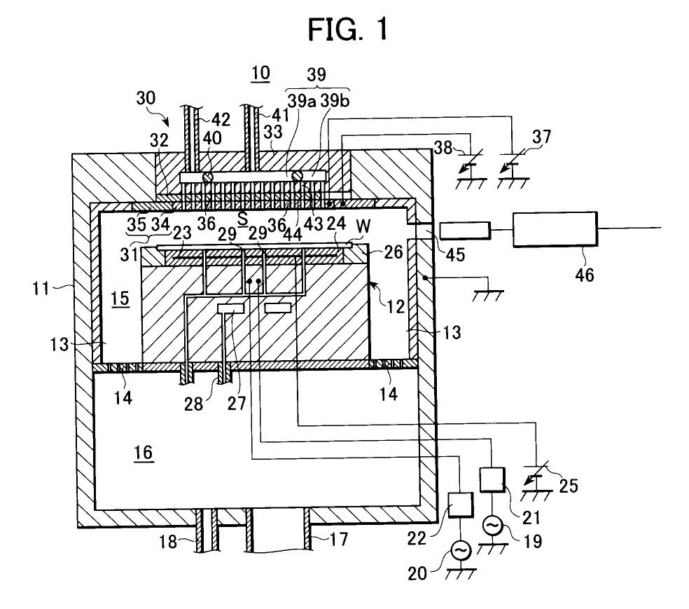

FIG. 1 is a cross-sectional view schematically showing the construction of a substrate processing apparatus as a plasma processing apparatus according to an embodiment of the present invention. The substrate processing apparatus is constructed such as to carry out plasma processing such as RIE (reactive ion etching) processing or ashing processing on a semiconductor wafer W as a substrate.

Referring to FIG. 1, the substrate processing apparatus 10 has a cylindrical processing chamber 11, and a cylindrical susceptor 12 as a mounting stage that is disposed in the processing chamber 11 and on which is mounted a semiconductor wafer (hereinafter referred to merely as a “wafer”) W having a diameter of, for example, 300 mm.

In the substrate processing apparatus 10, an exhaust path 13 that acts as a flow path through which gas in a processing space S, described later, is exhausted out of the chamber 11 is formed between an inner side wall of the processing chamber 11 and the side face of the susceptor 12. An exhaust plate 14 is disposed part way along the exhaust path 13.

The exhaust plate 14 is a plate-shaped member having a large number of holes therein and acts as a partition plate that partitions the processing chamber 11 into an upper portion and a lower portion. In the upper portion (hereinafter referred to as the “reaction chamber”) 15 of the processing chamber 11 partitioned by the exhaust plate 14, plasma is produced, described below. Exhaust pipes 17 and 18 through which gas in the processing chamber 11 is exhausted are connected to the lower portion (hereinafter referred to as the “exhaust chamber (manifold)”) 16 of the processing chamber 11. The exhaust plate 14 captures or reflects plasma produced in the reaction chamber 15 to prevent leakage of the plasma into the manifold 16.

The exhaust pipe 17 has a TMP (turbo-molecular pump) (not shown), and the exhaust pipe 18 has a DP (dry pump) (not shown) connected thereto. These pumps reduce the pressure in the processing chamber 11 down to a vacuum state. Specifically, the DP reduces the pressure in the processing chamber 11 from atmospheric pressure down to an intermediate vacuum state (e.g. a pressure of not more than 1.3×10 Pa (0.1 Torr)), and the TMP is operated in collaboration with the DP to reduce the pressure in the processing chamber 11 down to a high vacuum state (e.g. a pressure of not more than 1.3×10⁻³ Pa (1.0×10⁻⁵ Torr)), which is at a lower pressure than the intermediate vacuum state. It should be noted that an APC valve (not shown) controls the pressure in the processing chamber 11.

A first radio frequency power source 19 and a second radio frequency power source 20 are connected to the susceptor 12 in the processing chamber 11 via a first matcher 21 and a second matcher 22, respectively. The first radio frequency power source 19 supplies radio frequency electrical power of a relatively high frequency, for example, 60 MHz to the susceptor 12, and the second radio frequency power source 20 supplies radio frequency electrical power of a relatively low frequency, for example, 2 MHz to the susceptor 12. The susceptor 12 thus acts as a lower electrode that applies radio frequency electrical power to the processing space S between the susceptor 12 and a showerhead 30, described later.

An electrostatic chuck 24 that has an electrostatic electrode plate 23 therein and is comprised of a disk-shaped insulating member is disposed on an upper portion of the susceptor 12. When a wafer W is mounted on the susceptor 12, the wafer W is disposed on the electrostatic chuck 24. A DC power source 25 is electrically connected to the electrostatic electrode plate 23 of the electrostatic chuck 24. Upon a positive DC voltage being applied to the electrostatic electrode plate 23, a negative potential is produced on a surface of the wafer W which faces the electrostatic chuck 24 (hereinafter referred to as “the rear surface). A potential difference thus arises between the electrostatic electrode plate 23 and the rear surface of the wafer W, and hence the wafer W is attracted to and held on the electrostatic chuck 24 through a Coulomb force or a Johnsen-Rahbek force due to the potential difference.

Moreover, an annular focus ring 26 is mounted on the susceptor 12 such as to surround the attracted and held wafer W. The focus ring 26 is made of a conductive member such as silicon, and focuses plasma toward a front surface of the wafer W, thus improving the efficiency of the RIE processing.

An annular coolant chamber 27 that extends, for example, in a circumferential direction of the susceptor 12 is provided inside the susceptor 12. A coolant, for example, cooling water or a Galden (registered trademark) fluid, at a low temperature is circulated through the coolant chamber 27 via a coolant piping 28 from a chiller unit (not shown). The susceptor 12 cooled by the low-temperature coolant cools the wafer W and the focus ring 26 via the electrostatic chuck 24.

A plurality of heat transfer gas supply holes 29 are opened to a portion of the upper surface of the electrostatic chuck 24 on which the wafer W is attracted and held (hereinafter referred to as the “attracting surface”). Helium (He) gas as a heat transfer gas is supplied into a gap between the attracting surface and the rear surface of the wafer W via the heat transfer gas supply holes 29. The helium gas supplied into the gap between the attracting surface and the rear surface of the wafer W effectively transfers heat from the wafer W to the electrostatic chuck 24.

The showerhead 30 is disposed in a ceiling portion of the processing chamber 11. The showerhead 30 has an upper electrode 31 that is exposed to the processing space S and faces the wafer W mounted on the susceptor 12 (hereinafter referred to as the “mounted wafer W”), an insulating plate 32 comprised of an insulating member, and an electrode support 33 that suspends the upper electrode 31 therefrom via the insulating plate 32. The upper electrode 31, the insulating plate 32, and the electrode support 33 are superposed in this order.

The upper electrode 31 is comprised of an inner electrode 34 that faces a central portion of the mounted wafer W, and an outer electrode 35 that surrounds the inner electrode 34 and faces a peripheral edge portion of the mounted wafer W. The inner electrode 34 and the outer electrode 35 are each comprised of a conductive or semiconductive material such as single-crystal silicon.

The inner electrode 34 is comprised of a disk-shaped member having a diameter of, for example, 300 mm, and has a number of gas holes 36 penetrating the inner electrode 34 in the direction of thickness. The outer electrode 35 is comprised of an annular member having an outer diameter of, for example, 380 mm and an inner diameter of, for example, 300 mm.

In the upper electrode 31, a first DC power source 37 is connected to the inner electrode 34, a second DC power source 38 is connected to the outer electrode 35, and DC voltages are applied to the inner electrode 34 and the outer electrode 35 independently of each other.

The electrode support 33 has a buffer chamber 39 therein. The buffer chamber 39 is a cylindrical space whose central axis is coaxial with the central axis of the inner electrode 34, and is partitioned into an inner buffer chamber 39a and an outer buffer chamber 39b by an annular sealing member, for example, an O-ring 40.

A process gas introducing pipe 41 is connected to the inner buffer chamber 39a, and a process gas introducing pipe 42 is connected to the outer buffer chamber 39b. The process gas introducing pipes 41 and 42 introduce process gases into the inner buffer chamber 39a and the outer buffer chamber 39b, respectively.

Each of the process gas introducing pipes 41 and 42 has a flow rate controller (MFC) (not shown), and hence the flow rates of the process gases introduced into the inner buffer chamber 39a and the outer buffer chamber 39b are controlled independently of each other. Moreover, the buffer chamber 39 communicates with the processing space S via gas holes 43 of the electrode support 33, gas holes 44 of the insulating plate 32, and gas holes 36 of the inner electrode 34, and the process gases introduced into the inner buffer chamber 39a and the outer buffer chamber 39b are supplied into the processing space S. At this time, the distribution of the process gases in the processing space S is controlled by adjusting the flow rates of the process gases supplied into the inner buffer chamber 39a and the outer buffer chamber 39b.

A window 45 having, for example, quarts buried therein is provided in a side wall of the processing chamber 11, and a plasma emission spectroscopic unit 46 is disposed in the window 45. The plasma emission spectroscopic unit 46 divides plasma of a specific wavelength produced in the processing chamber 11 into spectrums, and detects, for example, that a chamber internal part has reached its end of longevity, and that the etching processing has been brought to an end based on a change in the status of plasma and a change in the intensity of plasma.

The above described chamber internal parts as consumables in the substrate processing apparatus 10, for example, the focus ring 26, the inner electrode 34, the outer electrode 35, and an insulator, not shown, constituting a side face of the susceptor 12 have respective longevity detecting elemental layers that are comprised of elements different from their constituent materials and buried at predetermined depths corresponding to surfaces susceptible to wear.

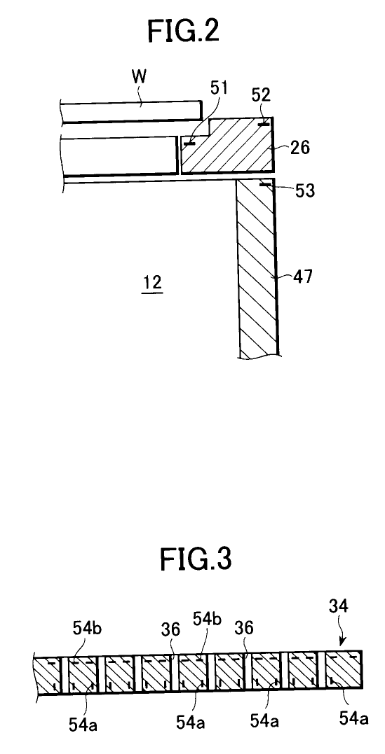

FIG. 2 is an enlarged cross-sectional view showing the focus ring 26 shown in FIG. 1 and the insulator 47 not shown in FIG. 1 as chamber internal parts as well as their vicinities.

Referring to FIG. 2, an upper surface close to an end portion of the wafer W and an upper surface facing the upper electrode (not shown) in the focus ring 26 are susceptible to wear. Thus, longevity detecting elemental layers 51 and 52 are buried correspondingly to the surfaces susceptible to wear.

The longevity detecting elemental layers 51 and 52 are provided at a depth of 750 μm below the respective surfaces corresponding to, for example, 750 μm that is the maximum permissible wear thickness of the focus ring 26. It should be noted that in the case that it is only necessary to detect that the focus ring 26 has reached its end of longevity, the longevity detecting elemental layers 51 and 52 may be provided at a greater depth than 750 μm, for example, at a depth of 760 μm.

The focus ring 26 is made of, for example, silicon, and the longevity detecting elemental layers 51 and 52 are comprised of, for example, scandium (Sc), which is an element other than Si and O. The scandium (Sc) produces a specific plasma emission spectrum having a particular peak over a wide wavelength range. Thus, if the focus ring 26 wears down to the maximum permissible wear thickness, and the longevity detecting elemental layer 51 or 52 exposes itself, a plasma emission spectrum arising from the scandium (Sc) that is the element forming the longevity detecting elemental layer 51 or 52 is produced over a wide wavelength range, a spectrum pattern different from a pattern before the longevity detecting elemental layers 51 or 52 exposes itself appears. Thus, by monitoring a change in spectrum pattern using the plasma emission spectroscopic unit 46, it can be detected that the longevity detecting elemental layer 51 or 52 has exposed itself, that is, the focus ring 26 has worn down to the maximum permissible wear thickness and reached its end of longevity.

Referring to FIG. 2, the insulator 47 is configured such that an upper surface thereof facing the focus ring 26 is most susceptible to wear, and hence a longevity detecting elemental layer 53 is buried correspondingly to this portion. The maximum permissible wear thickness of the insulator 47 is, for example, 2.4 mm, and the longevity detecting elemental layer 53 is provided at a depth of, for example, 2.4 mm below the surface. It should be noted that in the case that it is only necessary to detect that the insulator 47 has reached its end of longevity, the longevity detecting elemental layer 53 may be provided at a greater depth than 2.4 mm, for example, at a depth of 2.5 mm.

The insulator 47 is made of, for example, quarts, and the longevity detecting elemental layer 53 is comprised of, for example, thorium (Th), which is an element other than SiO₂. The thorium (Th) produces a plasma emission spectrum having a particular peak over a wide wavelength range. Thus, if the insulator 47 wears, and the longevity detecting elemental layer 53 exposes itself, a specific plasma emission spectrum arising from the thorium (Th) that is the element forming the longevity detecting elemental layer 53 is produced over a wide wavelength range, a spectrum pattern different from a pattern before the longevity detecting elemental layer 53 exposes itself appears. Thus, by monitoring a change in spectrum pattern using the plasma emission spectroscopic unit 46, it can be detected that the longevity detecting elemental layer 53 has exposed itself, that is, the insulator 47 has worn down to the maximum permissible wear thickness and reached its end of longevity.

FIG. 3 is an enlarged cross-sectional view showing the inner electrode 34 shown in FIG. 1. Referring to FIG. 3, portions of the inner electrode 34 which are most susceptible to wear are opening portions on the gas outlet side of the gas holes 36 (a lower surface as viewed in FIG. 3), and longevity detecting elemental layer are mainly buried in portions corresponding to the lower surface. The bore diameter of the gas holes 36 is, for example, 0.5 mm, and increases as wear occurs. The diameter-expanded portions of the gas holes 36 gradually go toward an upper surface of the inner electrode 34 as wearing of the lower surface occurs.

The maximum permissible bore diameter of the gas holes 36 is, for example, 2.5 mm. Thus, on the cross-sectional view of FIG. 3, longevity detecting elemental layers 54a are provided around the respective gas holes 36 having a bore diameter of, for example, 0.5 mm such as to face locations corresponding to a bore diameter of 2.5 mm. It should be noted that in the case that it is only necessary to detect that the inner electrode 34 has reached its end of longevity, the longevity detecting elemental layers 54a may be provided around the respective gas holes 36 having a bore diameter of, for example, 0.5 mm such as to face locations corresponding to a bore diameter of, for example, 2.6 mm on the cross-sectional view of FIG. 3.

On the other hand, the maximum permissible moving width of the diameter-expanded portions of the gas holes 36 is, for example, 9 mm from the lower surface. Thus, a plurality of longevity detecting elemental layer 54b are provided at a distance of 9 mm from the lower surface of the inner electrode 34 and in the vicinity of the gas holes 36 having a thickness of, for example, 10 mm. It should be noted that in the case that it is only necessary to detect that the inner electrode 34 has reached its end of longevity, the longevity detecting elemental layers 54b may be provided at a distance of, for example, 9.1 mm from the lower surface, at which wear has slightly proceeded from the maximum permissible moving width. The inner electrode 34 is made of, for example, silicon, and hence the longevity detecting elemental layers 54b are comprised of a metal other than Si and O, for example, neodymium (Nd).

It should be noted that the longevity detecting elemental layers 51 to 54 are provided correspondingly to not only the surfaces of the chamber internal parts which are most susceptible to wear, but also all the surfaces of the chamber internal parts. Whether the longevity detecting elemental layers 51 to 54 are to be buried correspondingly to the surfaces of the chamber internal parts which are most susceptible to wear or buried correspondingly to all the surfaces of the chamber internal parts may be determined in dependence on a chamber internal part manufacturing method, a longevity detecting elemental layer burying method, or the like.

The longevity detecting elemental layers in the chamber internal parts are formed using, for example, an ion implantation method. A description will now be given of a method of preparing the focus ring 26 provided with the longevity detecting elemental layers 51 and 52.

First, the focus ring 26 made of silicon is manufactured using a conventionally known method, and then longevity detecting elemental layers comprised of scandium (Sc), which is an element different from silicon, are buried. The scandium (Sc) is buried using, for example, ion implantation equipment to which an ion implantation method is applied.

The interior of the ion implantation equipment is maintained in a vacuum state of about 1×10⁻⁴ Pa, scandium (Sc) ions are prepared by an ion source, and the scandium (Sc) ions are accelerated by an electric field through an acceleration pipe. The accelerated scandium (Sc) ions are orientated by passing a direction control device such as a deflector or a slit through them. Then, a required mass of ions are selected by a mass analyzer and irradiated onto and scan predetermined locations of the focus ring 26 as a target using, for example, a scanner, so that the scandium (Sc) ions are implanted into predetermined locations of the focus ring 26 to form the longevity detecting elemental layers 51 and 52.

At this time, the depths of the scandium (Sc) ions, that is, the depths of the buried longevity detecting elemental layers are determined in dependence on ion species to be applied, the composition of the focus ring, the accelerating voltage, and so on. Thus, the burial depth can be accurately controlled. Moreover, the scandium (Sc) ions can be doped to irradiated portions due to the straightforwardness of beams, and hence the shape of the focus ring 26 as a member to be processed does not change. In the ion implantation method, a combination of a constituent material of a chamber internal part to be processed and a species of ions to be implanted can be freely selected, and similarly to the focus ring 26, other chamber internal parts also have longevity detecting elemental layers buried at depths corresponding to the maximum permissible wear thicknesses.

The longevity detecting elemental layers are buried by not only the ion implantation method, but also by, for example, forming films using different materials, or tucking films comprised of different materials in the process of manufacturing members.

In the substrate processing apparatus 10 in FIG. 1 in which the chamber internal parts having the above described longevity detecting elemental layers buried therein are incorporated, the mounted wafer W is subjected to the RIE processing.

When the mounted wafer W is to be subjected to the RIE processing, the showerhead 30 supplies a process gas into the processing space S, the first radio frequency power source 19 applies radio frequency electrical power of 60 MHz to the processing space S, and the second radio frequency power source 20 applies radio frequency electrical power of 2 MHz to the susceptor 12. At this time, the process gas is excited by the radio frequency electrical power of 60 MHz and turned into plasma. Moreover, the radio frequency electrical power of 2 MHz produces a bias voltage in the susceptor 12, and hence positive ions and electrons in the plasma are attracted to the front surface of the mounted wafer W, whereby the mounted wafer W is subjected to the RIE processing.

It should be noted that operation of the component parts of the substrate processing apparatus 10 described above is controlled by a CPU of a control unit (not shown) of the substrate processing apparatus 10.

At this time, in the substrate processing apparatus 10, the lives of the chamber internal parts are detected as described below.

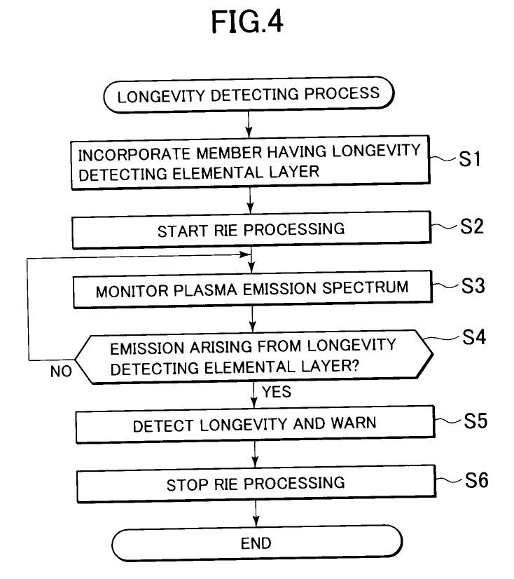

FIG. 4 is a flow chart showing the procedure of a method of detecting the lives of the chamber internal parts.

Referring to FIG. 4, first, the chamber internal parts having the respective longevity detecting elemental layers buried therein are incorporated into the substrate processing apparatus 10 as a plasma processing apparatus (step S1). Next, the RIE (reactive ion etching) processing on a wafer W is started using the substrate processing apparatus 10 having the chamber internal parts incorporated therein (step S2). After the RIE processing is started, a plasma emission spectrum in a process gas in the processing space is monitored at predetermined time intervals or on a regular basis using the plasma emission spectroscopic unit 46 (step S3). By monitoring the plasma emission spectrum in the process gas, the condition in the processing chamber 11 is detected.

It is then determined whether or not the emission spectrum arises from any of the longevity detecting elemental layers buried in the chamber internal parts (step S4). If, as a result of the determination, the emission spectrum arises from any of the longevity detecting elemental layers buried in the chamber internal parts, it is detected that the chamber internal part corresponding to the emission spectrum has reached its end of longevity, and an alert is issued (step S5), and then the RIE processing is brought to an end (step S6), followed by terminating the present process. On the other hand, if, as a result of the determination in the step S4, the emission spectrum does not arise from the longevity detecting elemental layers buried in the chamber internal parts, the process returns to the step S3, and the steps S3 and S4 are executed again.

According to the present embodiment, members in which the longevity detecting elemental layers 51 to 54 comprised of elements different from the constituent materials of the chamber internal parts are buried at depths corresponding to maximum permissible wear thicknesses are used as the chamber internal parts such as the focus ring 26. Thus, by monitoring an emission spectrum during the plasma processing and detecting an emission spectrum arising from any of the longevity detecting elemental layers, it can be accurately detected that the concerned chamber internal part has reached its end of longevity. Thus, it is possible to eliminate the waste of the replacement of a chamber internal part that has not reached its end of longevity and prevent the occurrence of troubles caused by continuously using a chamber internal part that has reached its end of longevity.

In the present embodiment, longevity detecting elemental layers comprised of metals different from the longevity detecting elemental layers 51 to 54 may be provided between the longevity detecting elemental layers 51 to 54 and the surfaces of the chamber internal parts and caused to act as an attention drawing layer. This can make it possible to predict in advance that the chamber internal parts will reach their ends of longevity, and reliably prevent inconveniences caused by the chamber internal parts reaching their ends of longevity. Moreover, a plurality of longevity detecting elemental layers may be provided between the longevity detecting elemental layers 51 to 54 formed at the depths corresponding to the maximum permissible wear thicknesses and the surfaces of the chamber internal parts so that the wear thicknesses of the chamber internal parts can be monitored all the time.

In the present embodiment, transition metals such as scandium (Sc), thorium (Th), and neodymium (Nd) are used as constituent elements of the longevity detecting elemental layers because elements that are not used in the chamber are preferably used, but other transition elements such as dysprosium (Dy), thulium (Tm), and holmium (Ho) may be used. These transition metals produce an emission spectrum over a wide wavelength range, and hence by detecting that the pattern of an emission spectrum has changed compared to before, it can be detected that the longevity detecting elemental layer has exposed itself.

As elements that form the longevity detecting elemental layers, not only transition elements but also alkali metals, alkali earth metals, and so on may be used. For example, sodium (Na) produces an intense emission spectrum in a wavelength range of 589 nm, potassium (K) produces an intense emission spectrum in a wavelength range of 766.770 nm, lithium (Li) produces an intense emission spectrum in a wavelength range of 670.611 nm, thallium (Tl) produces an intense emission spectrum in a wavelength range of 535 nm, indium (In) produces an intense emission spectrum in a wavelength range of 451 nm, and gallium (Ga) produces an intense emission spectrum in a wavelength range of 410 nm. Thus, an increase in the intensity of an emission spectrum in these particular wavelength ranges may be detected using a method such as temporal differentiation, and based on this detection result, it may be detected that the longevity detecting elemental layer has exposed itself and reached its end of longevity.

In the present embodiment, the chamber internal part is at least one of a focus ring, an electrode, an electrode protecting member, an insulator, an insulating ring, a bellows cover, and a baffle plate. These members are treated as so-called consumables, and hence their ends of longevity have to be monitored.

In the present embodiment, it is preferred that elements forming longevity detecting elemental layers buried in a focus ring, an insulator, an electrode, and so on are those which differ according to members in the chamber. Thus, chamber internal parts that have reached their ends of longevity can be accurately identified by detecting plasma emission spectrums specific to the respective elements.

In the present embodiment, a surface of a chamber internal part may be provided with a coating layer having a predetermined thickness comprised of an element different from a constituent member of the chamber internal part, and by detecting a plasma emission spectrum arising from an inner constituent member produced when the coating layer is worn, it can be detected that the chamber internal part has worn and reached its end of longevity.

Although in the above described embodiments, the substrates subjected to the etching processing are semiconductor wafers W, the substrate subjected to the etching processing are not limited to them and rather may instead be any of various glass substrates used in LCDs (Liquid Crystal Displays), FPDs (Flat Panel Displays), or the like. Moreover, the present invention may be applied to all plasma apparatuses such as a substrate processing apparatus, a semiconductor manufacturing apparatus, an FPD manufacturing apparatus, and a dry cleaning apparatus using plasma.

What is claimed is:

1. A chamber internal part applied to a plasma processing apparatus, comprising at least one longevity detecting elemental layer buried therein and comprised of an element different from a constituent material of the chamber internal part.

2. A chamber internal part as claimed in claim 1, wherein said longevity detecting elemental layer is buried correspondingly to a surface of the chamber internal part which is most susceptible to wear.

3. A chamber internal part as claimed in claim 1, wherein said longevity detecting elemental layer is buried at a depth corresponding to a maximum permissible wear thickness of the chamber internal part.

4. A chamber internal part as claimed in claim 3, wherein another longevity detecting elemental layer is provided between said longevity detecting elemental layer and the surface and is caused to act as an attention drawing layer, and a longevity detecting elemental layer that is provided at a location deeper than the attention drawing layer and of which depth corresponds to the maximum permissible wear thickness of the chamber internal part is caused to act as a warning layer.

5. A chamber internal part as claimed in claim 4, wherein the attention drawing layer and the warning layer comprise respective different elements.

6. A chamber internal part as claimed in claim 1, wherein the element different from the constituent material produces a plasma emission spectrum having a peak in a specific wavelength range or having a specific peak over a wide wavelength range.

7. A chamber internal part as claimed in claim 6, wherein the element comprises a metal.

8. A chamber internal part as claimed in claim 7, wherein the metal comprises a transition metal.

9. A chamber internal part as claimed in claim 8, wherein the transition metal is at least one of scandium (Sc), dysprosium (Dy), neodymium (Nd), thorium (Tm), holmium (Ho), and thorium (Th).

10. A chamber internal part as claimed in claim 1, wherein the chamber internal part is at least one of a focus ring, an electrode, an electrode protecting member, an insulator, an insulating ring, a bellows cover, and a baffle plate.

11. A plasma processing apparatus comprising a plurality of chamber internal parts, wherein longevity detecting elemental layers comprised of elements other than constituent materials of the chamber internal parts are buried in the respective ones of the plurality of chamber internal parts.

12. A plasma processing apparatus as claimed in claim 11, wherein the longevity detecting elemental layers comprise elements differing according to the chamber internal parts.

13. A method of detecting a longevity of a chamber internal part, comprising:
carrying out plasma processing using a plasma processing apparatus having incorporated therein at least one chamber internal part in which a longevity detecting elemental layer comprised of an element other than a constituent material is buried at a predetermined depth below a surface; and
detecting a plasma emission spectrum arising from the longevity detecting elemental layer to detect a longevity of the chamber internal part when the chamber internal part has worn due to plasma discharge.

14. A method of detecting a longevity of a chamber internal part as claimed in claim 13, wherein the plasma processing apparatus has the plurality of chamber internal parts incorporated therein, and the longevity detecting elemental layers in the plurality of chamber internal parts comprise respective different elements, and the chamber internal parts that have reached their ends of longevity are identified by detecting plasma emission spectrums specific to the respective elements.
